(19) United States
(12) Patent Application Publication
(10) Pub. No.: US 2020/0161367 A1
(43) Pub. Date: May 21, 2020

(54) IMAGING PANEL AND METHOD FOR PRODUCING SAME

(71) Applicant: Sharp Kabushiki Kaisha, Sakai City, Osaka (JP)

(72) Inventors: Katsunori MISAKI, Yonago-shi (JP); Kunio MATSUBARA, Yonago-shi (JP)

(21) Appl. No.: 16/628,275

(22) PCT Filed: Jul. 10, 2018
(86) PCT No.: PCT/JP2018/025985

§ 371 Date: Jan. 3, 2020

(30) Foreign Application Priority Data
Jul. 12, 2017 (JP) 2017-136056

(51) Int. Cl. H01L 27/146; G01T 1/20

(52) U.S. Cl. CPC H01L 27/14663; G01T 1/2006; H01L 27/14618; H01L 27/14683

(57) ABSTRACT

An imaging panel (1) generates an image based on scintillation light obtained from X-rays transmitted through an object. The imaging panel (1) has an active area and terminal areas on a substrate (100). A protection layer is provided in the active area and the terminal areas, on one of surfaces of the substrate. In the active area (P1), a plurality of elements including switching elements (13) are provided. In the terminal areas (P2, P3), terminal elements (131, 132) connected with any of the plurality of elements are provided. The protection layer includes a barrier layer (101a) in contact with the one surface of the substrate (100), and is provided in a lower layer with respect to the plurality of elements and the terminal elements (131, 132). The barrier layer (101a) contains a material having resistance against an etching material that can etch the substrate (100).

### TECHNICAL FIELD

The present invention relates to an imaging panel and a method for producing the same.

### BACKGROUND ART

An X-ray imaging device that picks up an X-ray image with an imaging panel that includes a plurality of pixel portions is known. In such an X-ray imaging device, irradiated X-rays are converted into charges by, for example, photodiodes. Converted charges are read out by thin film transistors (hereinafter also TFTs) that are caused to operate, the TFTs being provided in the pixel portions. The charges are read out in this way, whereby an X-ray image is obtained. Such an imaging panel is disclosed in JP-A-2013-46043.

Incidentally, elements such as the above-described TFTs and photodiodes are formed on a substrate made of glass or the like. When an imaging panel is formed, after elements such as TFTs and photodiodes are formed, the substrate is subjected to thin plate processing with use of a liquid mixture containing hydrofluoric acid in some cases, for the purpose of reducing the weight of the imaging panel. In the thin plate processing, if there is a scar on the substrate, the processing speed increases at the portion of the scar, and a dimple is formed there. Further, here, if a part of the TFT, an insulating layer, or the like disappear in the portion where the dimple is formed, line disconnection occurs.

It is an object of the present invention to provide an X-ray imaging panel that is lightweight without occurrence of line disconnection, and a method for producing the same.

### SUMMARY OF THE INVENTION

An imaging panel of the present invention that solves the above-described problem is an imaging panel that generates an image based on scintillation light that is obtained from X-rays transmitted through an object. The imaging panel includes: a substrate; an active area formed on one of surfaces of the substrate; a terminal area provided on an outer side with respect to the active area; and a protection layer provided in the active area and the terminal area on the one of surfaces of the substrate. The active area has a plurality of elements including switching elements.

The terminal area has a terminal element connected with any of the plurality of elements. The protection layer includes a barrier layer in contact with the one of surfaces of the substrate, and is provided in a lower layer with respect to the plurality of elements and the terminal element. The barrier layer contains a material having resistance against an etching material that can etch the substrate.

With the present invention, an X-ray imaging panel that is lightweight without occurrence of line disconnection can be provided.

### BRIEF DESCRIPTION OF DRAWINGS

FIG. 1 schematically illustrates an X-ray imaging device in an embodiment.

FIG. 2 schematically illustrates a schematic configuration of an imaging panel illustrated in FIG. 1.

FIG. 3 is a plan view schematically illustrating one pixel portion of the imaging panel illustrated in FIG. 2.

FIG. 4 is a cross-sectional view illustrating the pixel illustrated in FIG. 3, taken along line A-A.

FIG. 5 is a plan view schematically illustrating a G terminal area in the imaging panel illustrated in FIG. 1.

FIG. 6 is a plan view schematically illustrating a S terminal area and a B terminal area in the imaging panel illustrated in FIG. 1.

FIG. 7 illustrate a cross section of the G terminal area illustrated in FIG. 5, taken along line B-B, as well as a cross section of the B terminal area illustrated in FIG. 6, taken along line C-C.

FIG. 8A is a cross-sectional view for explaining illustrating a step in a process for producing the pixel area and the terminal area, the step being a step of forming a barrier layer, an inorganic insulating film, and a metal film as a gate electrode on a substrate sequentially.

FIG. 8B is a cross-sectional view illustrating a step of patterning the metal film illustrated in FIG. 8A.

FIG. 8C is a cross-sectional view illustrating a step of forming an oxide semiconductor in the pixel area.

FIG. 8D is a cross-sectional view illustrating a step of forming a metal film as a source electrode and a drain electrode in the pixel area and the terminal area.

FIG. 8E is a cross-sectional view illustrating a step of patterning the metal film illustrated in FIG. 8D.

FIG. 8F is a cross-sectional view illustrating a step of forming a first insulating film in the pixel area and the terminal area.

FIG. 8G is a cross-sectional view illustrating a step of patterning the first insulating film illustrated in FIG. 8F.

FIG. 8H is a cross-sectional view illustrating a step of forming a second insulating film in the pixel area and the terminal area.

FIG. 8I is a cross-sectional view illustrating a step of patterning the second insulating film illustrated in FIG. 8H.

FIG. 8J is a cross-sectional view illustrating a step of forming a lower electrode in the pixel area.

FIG. 8K is a cross-sectional view illustrating a step of forming a semiconductor layer and a transparent conductive film as an upper electrode in the pixel area and the terminal area.

FIG. 8L is a cross-sectional view illustrating a step of patterning the transparent conductive film illustrated in FIG. 8K.

FIG. 8M is a cross-sectional view illustrating a step of patterning the semiconductor layer illustrated in FIG. 8L.

FIG. 8N is a cross-sectional view illustrating a step of forming a third insulating film in the pixel area and the terminal area.

FIG. 8O is a cross-sectional view illustrating a step of patterning the third insulating film illustrated in FIG. 8N.

FIG. 8P is a cross-sectional view illustrating a step of forming a fourth insulating film in the pixel area and the terminal area.

FIG. 8Q is a cross-sectional view illustrating a step of patterning the fourth insulating film illustrated in FIG. 8P.

FIG. 8R is a cross-sectional view illustrating a step of forming a metal film as a bias line in the pixel area and the terminal area.

FIG. 8S is a cross-sectional view illustrating a step of patterning the metal film illustrated in FIG. 8R.

FIG. 8T is a cross-sectional view illustrating a step of forming a transparent conductive film in the pixel area and the terminal area.

FIG. 8U is a cross-sectional view illustrating a step of patterning the transparent conductive film illustrated in FIG. 8T.

FIG. 8V is a cross-sectional view illustrating a step of forming a fifth insulating film in the pixel area and the terminal area.

FIG. 8W is a cross-sectional view illustrating a step of forming a sixth insulating film in the pixel area and the terminal area.

FIG. 8X is a cross-sectional view illustrating a step of patterning the sixth insulating film illustrated in FIG. 8W.

FIG. 8Y is a cross-sectional view illustrating a state of the substrate illustrated in FIG. 8X that has been subjected to thin plate processing.

### MODE FOR CARRYING OUT THE INVENTION

An imaging panel according to an embodiment of the present invention is an imaging panel that generates an image based on scintillation light that is obtained from X-rays transmitted through an object, and the imaging panel includes: a substrate; an active area formed on one of surfaces of the substrate; a terminal area provided on an outer side with respect to the active area; and a protection layer provided in the active area and the terminal area on the one of surfaces of the substrate, wherein the active area has a plurality of elements including switching elements, wherein the terminal area has a terminal element connected with any of the plurality of elements, wherein the protection layer includes a barrier layer in contact with the one of surfaces of the substrate, and is provided in a lower layer with respect to the plurality of elements and the terminal element, and wherein the barrier layer contains a material having resistance against an etching material that can etch the substrate (the first configuration).

According to the first configuration, the protection layer is provided in a lower layer with respect to the plurality of elements in the active area and the terminals in the terminal area. The protection layer includes a barrier layer having resistance against an etching material used in the etching of the substrate. Therefore, in the thin plate processing performed when an imaging panel is produced, the protection layer makes it unlikely that a part of the elements in the active area and the terminals in the terminal area would disappear, even if there is a scar or the like on the substrate. As a result, an imaging panel that is lightweight without occurrence of line disconnection in the active area and the terminal area can be obtained.

The first configuration may be further characterized in that the protection layer further includes an inorganic insulating film in contact with the barrier layer, and the inorganic insulating film is provided in a lower layer with respect to the plurality of elements and the terminal element (the second configuration). According to second configuration, the inorganic insulating film and the barrier layer are arranged so as to overlap with each other in a lower layer with respect to the plurality of elements and the terminal element. Therefore, even if a dimple is formed on the substrate in the thin plate processing performed when an imaging panel is produced, it is unlikely that contaminants such as moisture would enter through the dimple portion and adversely affect properties of the switching elements in the active area.

The first or second configuration may be further characterized in that the barrier layer is formed with a conductive film (the third configuration).

The first or second configuration may be further characterized in that the barrier layer is formed with a semiconductor film (the fourth configuration).

The first or second configuration may be further characterized in that the barrier layer is formed with an organic insulating film (the fifth configuration).

A method for producing an imaging panel according to an embodiment of the present invention is a method for producing an imaging panel that generates an image based on scintillation light that is obtained from X-rays transmitted through an object, and the imaging panel producing method includes the steps of: forming a barrier layer in an active area and a terminal area on one of surfaces of a substrate; forming a plurality of elements including switching elements, in an upper layer with respect to the barrier layer in the active area; forming a terminal element in an upper layer with respect to the inorganic insulating film in the terminal area; and etching the substrate, wherein the barrier layer contains a material having resistance against an etching material used in the step of etching the substrate (the first producing method).

According to the first producing method, a barrier layer is provided in a lower layer with respect to the plurality of elements in the active area and the terminals in the terminal area. The barrier layer has resistance against an etching material used in the step of etching the substrate. In the step of etching the substrate, the barrier layer makes it unlikely that a part of the elements such as switching elements in the active area and the terminals in the terminal area would disappear, even if there is a scar or the like on the substrate. Therefore, an imaging panel that is lightweight without occurrence of line disconnection in the active area and the terminal area can be produced.

The first producing method may be further characterized in further including the step of forming an inorganic insulating film on the barrier layer, wherein the plurality of elements are formed in an upper layer with respect to the inorganic insulating film (the second producing method). According to the second producing method, the inorganic insulating film and the barrier layer are arranged so as to overlap with each other in a lower layer with respect to the plurality of elements and the terminal element. Therefore, even if a dimple is formed on the substrate in the thin plate processing performed when an imaging panel is produced, it is unlikely that contaminants such as moisture would enter through the dimple portion and adversely affect properties of the switching elements in the active area.

The first or second producing method may be further characterized in that the etching material contains hydrofluoric acid (the third producing method).

The following description describes an embodiment of the present invention in detail, while referring to the drawings. Identical or equivalent parts in the drawings are denoted by the same reference numerals, and the descriptions of the same are not repeated.

### (Configuration)

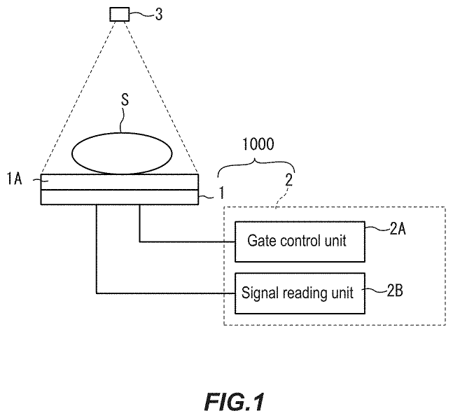

FIG. 1 is a schematic diagram illustrating an X-ray imaging device in the present embodiment. The X-ray imaging device 1000 includes an imaging panel 1 and a control unit 2. The control unit 2 includes a gate control unit 2A and a signal reading unit 2B. X-rays are projected from the X-ray source 3 to an object S, and X-rays transmitted through the object S are converted into fluorescence (hereinafter referred to as scintillation light) by a scintillator 1A arranged above the imaging panel 1. The X-ray imaging device 1000 acquires an X-ray image by picking up the scintillation light with the imaging panel 1 and the control unit 2.

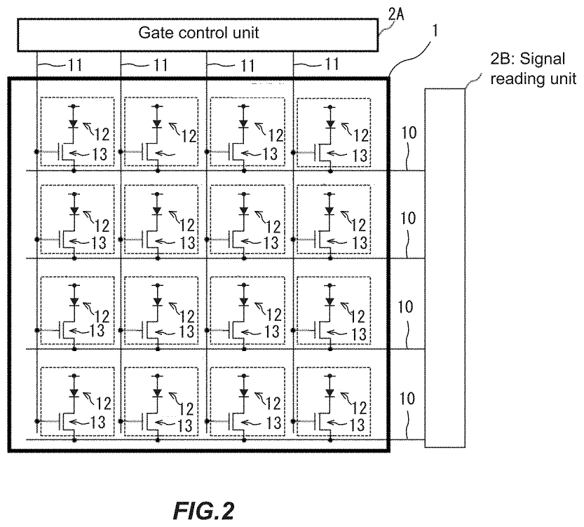

FIG. 2 is a schematic diagram illustrating a schematic configuration of the imaging panel 1. As illustrated in FIG. 2, a plurality of source lines 10, and a plurality of gate lines 11 intersecting with the source lines 10 are formed in the imaging panel 1. The gate lines 11 are connected with the gate control unit 2A, and the source lines 10 are connected with the signal reading unit 2B.

The imaging panel 1 includes TFTs 13 connected to the source lines 10 and the gate lines 11, at positions at which the source lines 10 and the gate lines 11 intersect. Further, photodiodes 12 are provided in areas surrounded by the source lines 10 and the gate lines 11 (hereinafter referred to as pixels). In each pixel, scintillation light obtained by converting X-rays transmitted through the object S is converted by the photodiode 12 into charges according to the amount of the light.

The gate lines 11 are sequentially switched by the gate control unit 2A into a selected state, and the TFT 13 connected to the gate line 11 in the selected state is turned ON. When the TFT 13 is turned ON, a signal according to the charges obtained by the conversion by the photodiode 12 is output through the source line 10 to the signal reading unit 2B.

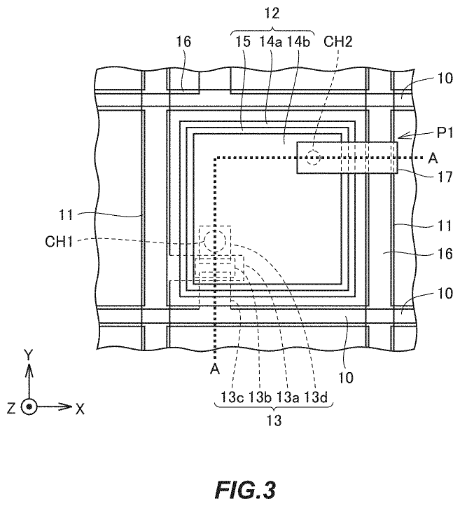

FIG. 3 is an enlarged plan view of a part of a pixel area (hereinafter referred to as an “active area”) where the pixels are formed in the imaging panel 1. As illustrated in FIG. 3, in the pixel surrounded by the gate lines 11 and the source lines 10, a lower electrode 14a, a photoelectric conversion layer 15, and an upper electrode 14b that compose the photodiode 12 are arranged so as to overlap with one another.

Further, a bias line 16 is arranged so as to overlap with the gate line 11 and the source line 10 when viewed in a plan view. The bias line 16 supplies a bias voltage to the photodiode 12.

The TFT 13 includes a gate electrode 13a provided integrally with the gate line 11, a semiconductor active layer 13b, a source electrode 13c provided integrally with the source line 10, and a drain electrode 13d.

The drain electrode 13d and the lower electrode 14a are connected with each other through a contact hole CH1. A transparent conductive film 17 that is arranged so as to overlap with the bias line 16, and the transparent conductive film 17 and the upper electrode 14b are connected with each other through the contact hole CH2.

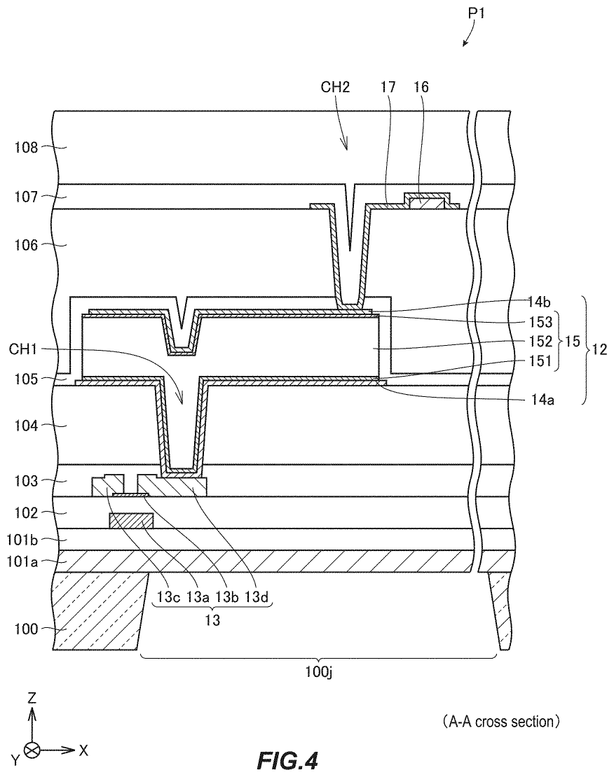

Here, FIG. 4 illustrates a cross section of the pixel area illustrated in FIG. 3, taken along line A-A. As illustrated in FIG. 4, the substrate 100 has a dimple 100j on a back surface thereof, i.e., on a surface on a side opposite to the side to which X-ray is projected. The substrate 100 is a substrate having insulating properties, for example, a glass substrate, a silicon substrate, a plastic substrate having heat-resisting properties, a resin substrate, or the like.

Over a part of the surface of the substrate 100 on the side opposite to the side of the back surface, where the pixel area is to be formed, a barrier layer 101a is provided. The barrier layer 101a covers the part of the dimple 100j formed in the substrate 100. The barrier layer 101a contains a material having etching resistance against hydrofluoric acid. More specifically, the barrier layer 101a includes a conductive film made of, for example, any one of molybdenum (Mo), tungsten (W), tantalum (Ta), lead (Pb), and indium tin oxide (ITO). The barrier layer 101a has a thickness of, for example, about 300 nm.

On the barrier layer 101a, an inorganic insulating film 101b is arranged so as to cover the barrier layer 101a. The inorganic insulating film 101b contains, for example, silicon oxide (SiO₂), silicon nitride (SiN), or silicon oxide nitride (SiON). The inorganic insulating film 101b has a thickness of, for example, about 300 nm.

On the inorganic insulating film 101b, the gate electrode 13a provided integrally with the gate line 11 is formed. The gate electrode 13a and the gate line 11 are made of, for example, a metal such as aluminum (Al), tungsten (W), molybdenum (Mo), molybdenum nitride (MoN), tantalum (Ta), chromium (Cr), titanium (Ti), or copper (Cu), an alloy of any of these metals, or a metal nitride of these metals. In the present embodiment, the gate electrode 13a and the gate line 11 have a laminate structure that is obtained by laminating a metal film made of titanium (Ti), and a metal film made of aluminum (Al) in this order. Regarding thicknesses of these metal films, for example, the metal film made of titanium has a thickness of about 100 nm, and the metal film made of aluminum has a thickness of about 300 nm.

On the inorganic insulating film 101b, a gate insulating film 102 is provided so as to cover the gate electrode 13a. The gate insulating film 102 may be formed with, for example, silicon oxide (SiO₂), silicon nitride (SiN), silicon oxide nitride (SiOₓN_{y}) (x>y), or silicon nitride oxide (SiNₓO_{y}) (x>y). In the present embodiment, the gate insulating film 102 has a laminate structure obtained by laminating silicon oxide (SiO₂) and silicon nitride (SiN) in the order. Regarding the film thickness of the gate insulating film 102, the film of silicon oxide (SiO₂) has a thickness of about 50 nm, and the film of silicon nitride (SiN) has a thickness of about 400 nm.

The semiconductor active layer 13b, as well as the source electrode 13c and the drain electrode 13d connected with the semiconductor active layer 13b are formed on the gate electrode 13a with the gate insulating film 102 being interposed therebetween.

The semiconductor active layer 13b is formed in contact with the gate insulating film 102. The semiconductor active layer 13b is made of an oxide semiconductor. As the oxide semiconductor, for example, the following material may be used: InGaO₃(ZnO)₅; magnesium zinc oxide (MgₓZn₁₋ₓO); cadmium zinc oxide (CdₓZn₁₋ₓO); cadmium oxide (CdO); InSnZnO (containing indium (In), tin (Sn), and zinc (Zn)); material based on indium (In)-aluminum (Al)-zinc (Zn)-oxygen (O); or an amorphous oxide semiconductor containing indium (In), gallium (Ga), and zinc (Zn) at a predetermined ratio. Further, as an oxide semiconductor, “amorphous” materials, and “crystalline” materials (including polycrystalline materials, microcrystalline materials, and c-axis alignment crystalline materials) are applicable. In the case of the laminate structure, any combination is applicable (any particular combination is not excluded).

In the present embodiment, the semiconductor active layer 13b is made of an amorphous oxide semiconductor containing indium (In), gallium (Ga), and zinc (Zn) at a predetermined ratio, and has a thickness of, for example, 70 nm. By applying a semiconductor active layer 13b, and an oxide semiconductor containing indium (In), gallium (Ga), zinc (Zn), and oxygen (O), off-leakage current of the TFT 13 can be reduced, as compared with amorphous silicon(a-Si). When off-leakage current of the TFT 13 is small, off-leakage current of the photoelectric conversion layer 15 is also reduced, whereby quantum efficiency (QE) of the photoelectric conversion layer 15 is improved, which results in that the X-ray detection sensitivity can be improved.

The source electrode 13c and the drain electrode 13d are formed in contact with the semiconductor active layer 13b and the gate insulating film 102. The source electrode 13c is provided integrally with the source line 10. The drain electrode 13d is connected with the lower electrode 14a through the contact hole CH1.

The source electrode 13c and the drain electrode 13d are formed in the same layer, and are made of, for example, a metal such as aluminum (Al), tungsten (W), molybdenum (Mo), tantalum (Ta), chromium (Cr), titanium (Ti), or copper (Cu), or alternatively, an alloy of any of these, or a metal nitride of any of these. Further, as the material for the source electrode 13c and the drain electrode 13d, the following material may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or a material obtained by appropriately combining any of these.

The source electrode 13c and the drain electrode 13d may be, for example, a laminate of a plurality of metal films. More specifically, the source electrode 13c, the source line 10, and the drain electrode 13d have a laminate structure in which a metal film made of titanium (Ti), a metal film made of aluminum (Al), and a metal film made of titanium (Ti) are laminated in this order. The film made of titanium (Ti) in the lower layer has a thickness of about 100 nm, the film made of aluminum (Al) has a thickness of about 500 nm, and the film made of titanium (Ti) in the upper layer has a thickness of about 50 nm.

A first insulating film 103 is provided so as to cover the source electrode 13c and the drain electrode 13d. The first insulating film 103 may have a single layer structure made of silicon oxide (SiO₂) or silicon nitride (SiN), or a laminate structure obtained by laminating silicon nitride (SiN) and silicon oxide (SiO₂) in this order. In the case where the first insulating film 103 has a laminate structure, the film of silicon nitride (SiN) has a thickness of about 330 nm, and the film of silicon oxide (SiO₂) has a thickness of about 200 nm.

On the first insulating film 103, a second insulating film 104 is provided. The second insulating film 104 is made of, for example, an organic transparent resin such as acrylic resin or siloxane-based resin, and has a thickness of, for example, 2.5 μm.

On the drain electrode 13d, a contact hole CH1, passing through the second insulating film 104 and the first insulating film 103, is formed.

On the second insulating film 104, the lower electrode 14a, which is connected with the drain electrode 13d at the contact hole CH1, is formed. The lower electrode 14a is made of, for example, molybdenum niobium (MoN), and has a thickness of, for example, 200 μm.

The photoelectric conversion layer 15, whose width in X-axis direction is smaller than that of the lower electrode 14a, is formed on the lower electrode 14a. The photoelectric conversion layer 15 has a PIN structure that is obtained by laminating an n-type amorphous semiconductor layer 151, an intrinsic amorphous semiconductor layer 152, and a p-type amorphous semiconductor layer 153 in the order.

The n-type amorphous semiconductor layer 151 is made of amorphous silicon doped with an n-type impurity (for example, phosphorus). The n-type amorphous semiconductor layer 151 has a thickness of, for example, 30 nm.

The intrinsic amorphous semiconductor layer 152 is made of intrinsic amorphous silicon. The intrinsic amorphous semiconductor layer 152 is formed in contact with the n-type amorphous semiconductor layer 151. The intrinsic amorphous semiconductor layer has a thickness of, for example, 1000 nm.

The p-type amorphous semiconductor layer 153 is made of amorphous silicon doped with a p-type impurity (for example, boron). The p-type amorphous semiconductor layer 153 is formed in contact with the intrinsic amorphous semiconductor layer 152. The p-type amorphous semiconductor layer 153 has a thickness of, for example, 5 nm.

On the p-type amorphous semiconductor layer 153, the upper electrode 14b is formed. The upper electrode 14b has a smaller width in the X-axis direction than that of the photoelectric conversion layer 15. The upper electrode 14b is made of, for example, indium tin oxide (ITO), and has a thickness of, for example, 70 nm.

A third insulating film 105 is formed so as to cover the photodiode 12. The third insulating film 105 is, for example, an inorganic insulating film made of silicon nitride (SiN), and has a thickness of, for example, 300 nm.

In the third insulating film 105, the contact hole CH2 is formed at a position that overlaps with the upper electrode 14b.

On the third insulating film 105, in an area thereof outside the contact hole CH2, a fourth insulating film 106 is formed. The fourth insulating film 106 is formed with, for example, an organic transparent resin film made of acrylic resin or siloxane-based resin, and has a thickness of, for example, 2.5 μm.

On the fourth insulating film 106, the bias line 16 is formed. The bias line 16 has a laminate structure that is obtained by laminating, for example, a metal film made of titanium (Ti), a metal film made of aluminum (Al), and a metal film made of titanium (Ti) in this order. The film made of titanium (Ti) in the lower layer has a thickness of about 100 nm, the film made of aluminum (Al) has a thickness of about 500 nm, and the film made of titanium (Ti) in the upper layer has a thickness of about 50 nm.

On the fourth insulating film 106, the transparent conductive film 17 is formed so as to overlap with the bias line 16. The transparent conductive film 17 is in contact with the upper electrode 14b at the contact hole CH2. The transparent conductive film 17 is made of, for example, ITO, and has a thickness of about 70 nm.

The bias line 16 is connected to the control unit 2 (see FIG. 1). The bias line 16 applies a bias voltage through the conductive film 17 and the contact hole CH2 to the upper electrode 14b, the bias voltage being input from the control unit 2.

On the fourth insulating film 106, a fifth insulating film 107 is formed so as to cover the transparent conductive film 17. The fifth insulating film 107 is, for example, an inorganic insulating film made of silicon nitride (SiN), and has a thickness of about 200 nm.

On the fifth insulating film 107, a sixth insulating film 108 is formed. The sixth insulating film 108 is formed with, for example, an organic transparent resin such as acrylic resin or siloxane-based resin, and has a thickness of about 2.0 μm.

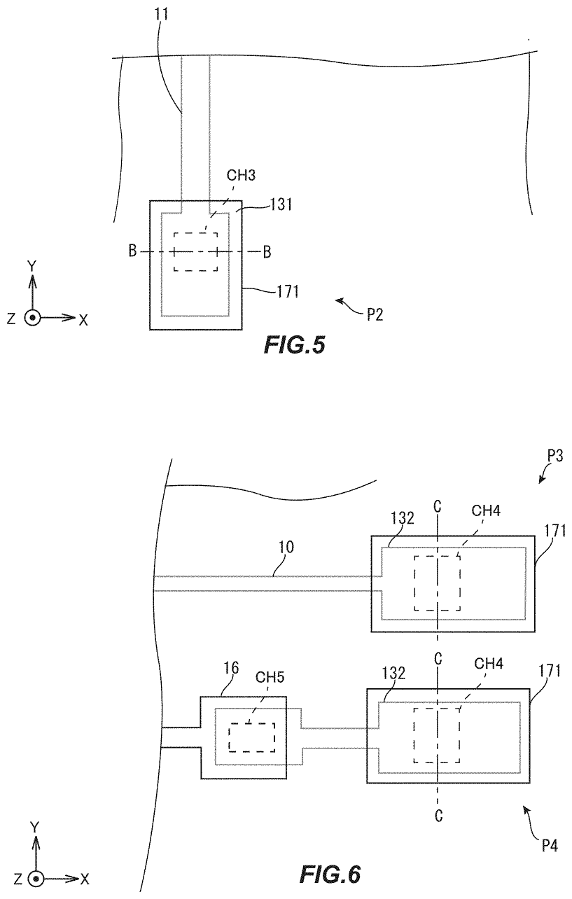

Here, enlarged plan views of a part of an area outside the pixel area (hereinafter referred to as an “active area”) of the imaging panel 1 are illustrated in FIGS. 5 and 6.

FIG. 5 illustrates a terminal area P2 where a terminal (hereinafter referred to as a “G terminal”) for connecting the gate electrode 13a and the gate line 11 illustrated in FIG. 3 with the gate control unit 2A (see FIG. 1) is provided.

FIG. 6 illustrates the following areas: a terminal area P3 where a terminal (hereinafter referred to as an “S terminal”) for connecting the source electrode 31c and the source line 10 illustrated in FIG. 3 with the signal reading part 2B (see FIG. 1) is provided; and a terminal area P4 where a terminal (hereinafter referred to as a “B terminal”) for connecting the bias line 16 illustrated in FIG. 3 with the control unit 2 is provided. The terminal B is connected with the bias line 16 through the contact hole CH5. Hereinafter, the terminal area P2 is referred to as a G terminal area, the terminal area P3 is referred to as an S terminal area, and the terminal area P4 is referred to as a B terminal area; when these are distinguished, they are simply referred to as terminal areas.

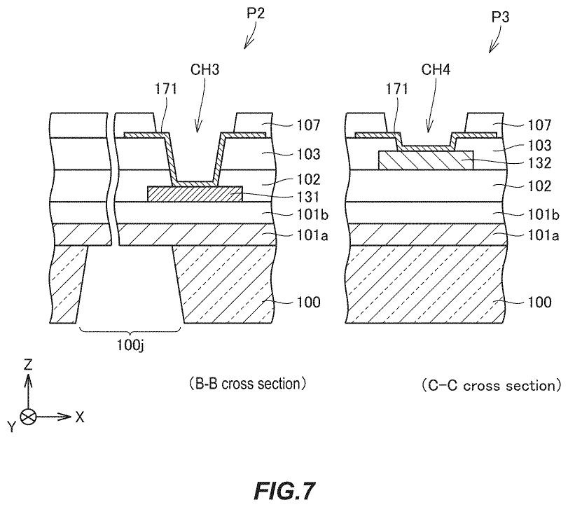

FIG. 7 illustrates a cross section of the G terminal area P3 illustrated in FIG. 5, taken along line B-B, as well as a cross section of the S terminal area P3 and the B terminal area P4 illustrated in FIG. 6, taken along line C-C. In FIG. 7, the same constituent members as those in the configuration of the pixel area illustrated in FIG. 4 are denoted by the same reference symbols as those in FIG. 4. As the S terminal area P3 and the B terminal area P4 have the same terminal structure, the S terminal area P3 is described as an example in the following description.

### (G Terminal Area)

As illustrated in FIG. 7, the G terminal area P2 has a dimple 100j identical to that in the pixel area, on a back surface of the substrate 100. On the surface of the substrate 100 on the side opposite to the side of the back surface, a barrier layer 101a identical to that in the pixel area is provided so as to cover the dimple 100j. Besides, on the barrier layer 101a, an inorganic insulating film 101b identical to that in the pixel area is provided.

On the inorganic insulating film 101b, a gate layer 131 is arranged. The gate layer 131 is connected with the gate electrodes 13a and the gate lines 11 provided in the pixel area (see FIGS. 2, 3), and is formed integrally with the gate electrodes 13a and the gate lines 11.

On the gate layer 131, a gate insulating film 102 is provided, and a first insulating film 103 is provided on the gate insulating film 102. Further, on the gate layer 131, a contact hole CH3 that passes through the gate insulating film 102 and the first insulating film 103 is provided.

On the first insulating film 103, a transparent conductive layer 171 that is connected with the gate layer 131 through the contact hole CH3 is provided. The transparent conductive layer 171 is formed with the same material as that of the transparent conductive film 17 provided in the pixel area (see FIG. 4).

On the first insulating film 103 and the transparent conductive layer 171, a fifth insulating film 107 is provided, outside the contact hole CH3.

### (S Terminal Area)

As illustrated in FIG. 7, in the S terminal area P3, on the back surface side of the substrate 100, a barrier layer 101a identical to that in the pixel area is provided, and on the barrier layer 101a, an inorganic insulating film 101b identical to that in the pixel area is provided.

On the inorganic insulating film 101b, a gate insulating film 102 is provided, and a source layer 132 is provided on the gate insulating film 102. The source layer 132 is formed integrally with the source electrode 13c and the source line 10 provided in the pixel area (see FIGS. 3 and 4).

On the source layer 132, the first insulating film 103 is arranged so as to have separation so that the contact hole CH4 is provided. Incidentally, the source layer 132 in the B terminal area P4 is connected with the bias line 16 through the contact hole CH5 (see FIG. 6).

On the first insulating film 103, the transparent conductive layer 171 that is connected with the source layer 132 through the contact hole CH4 is arranged.

On the first insulating film 103 and the transparent conductive layer 171, a fifth insulating film 107 is provided, outside the contact hole CH4.

### (Method for Producing Imaging Panel 1)

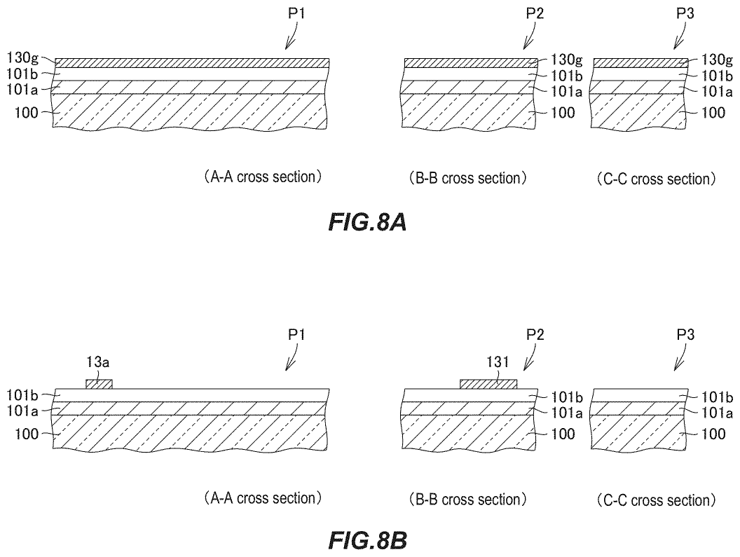

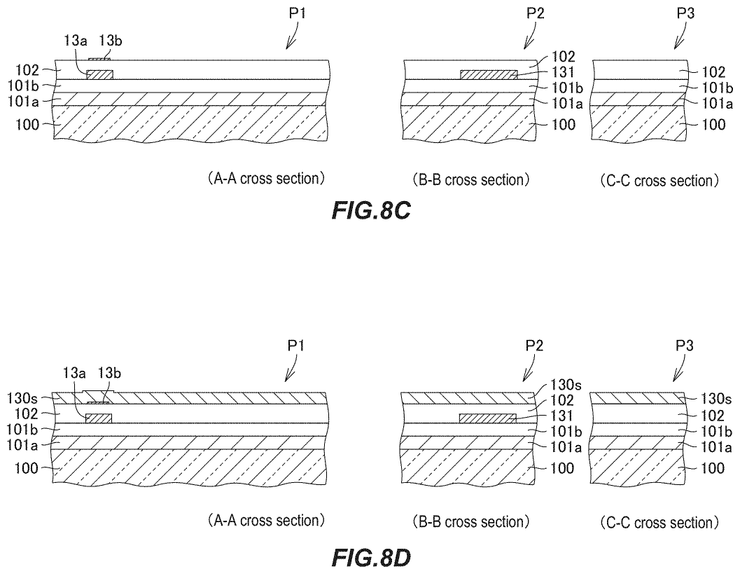

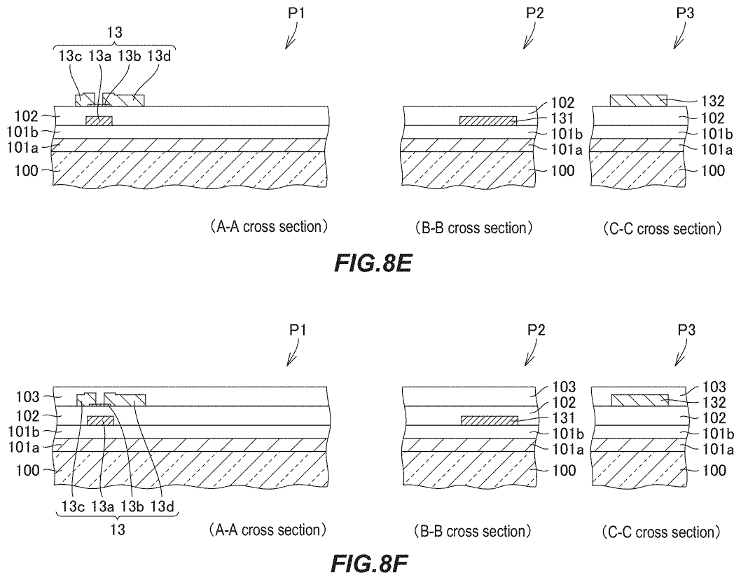

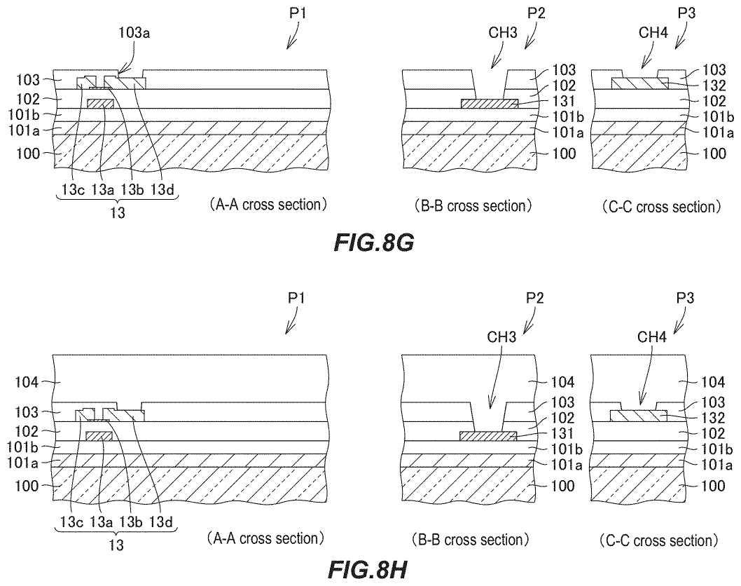

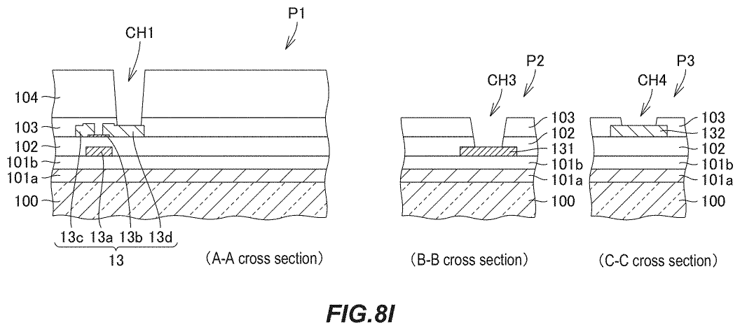

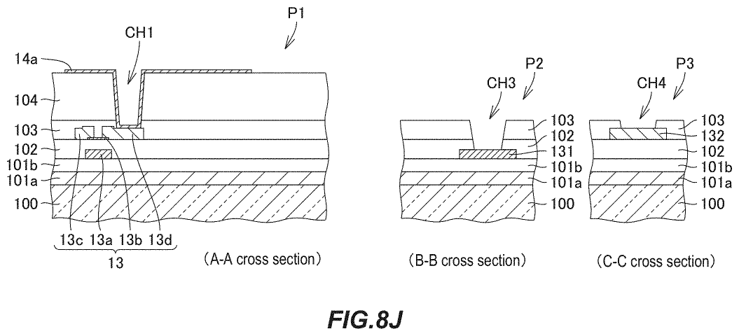

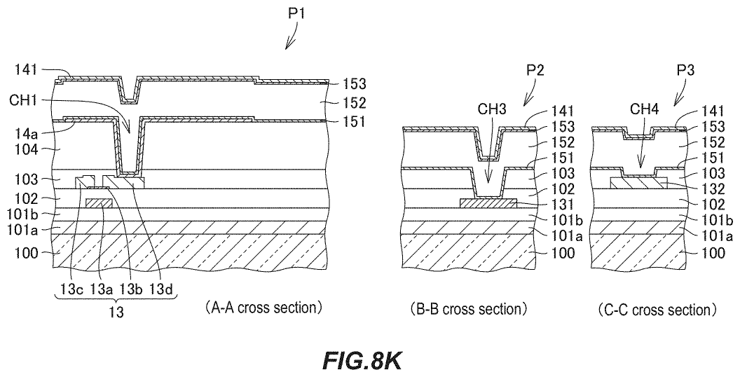

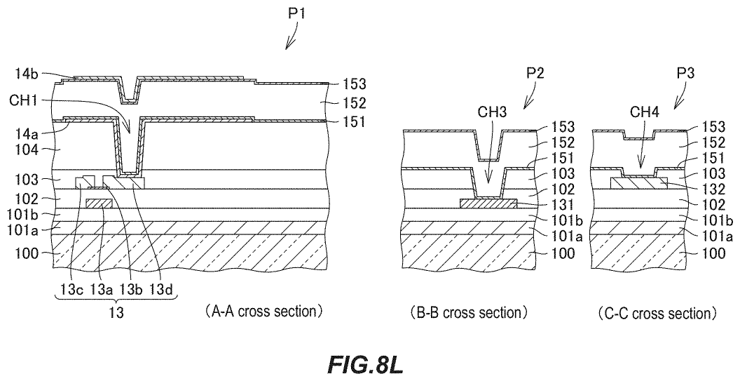

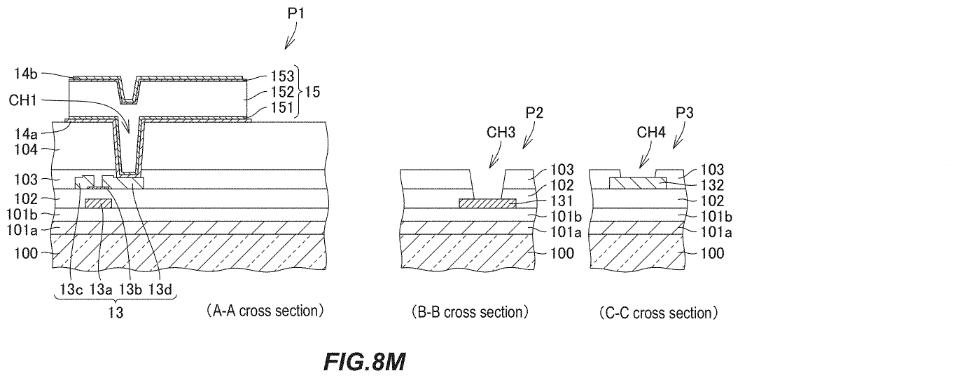

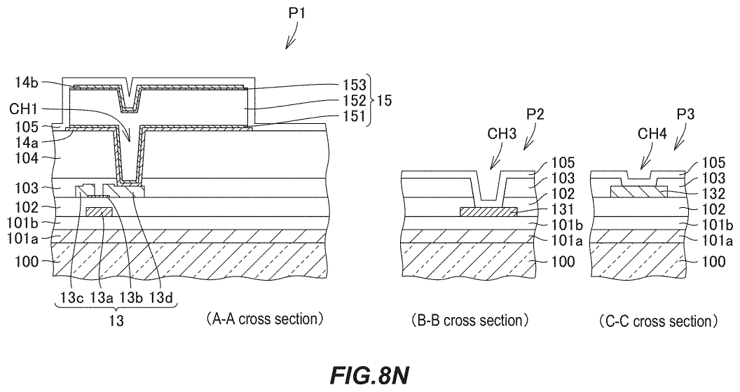

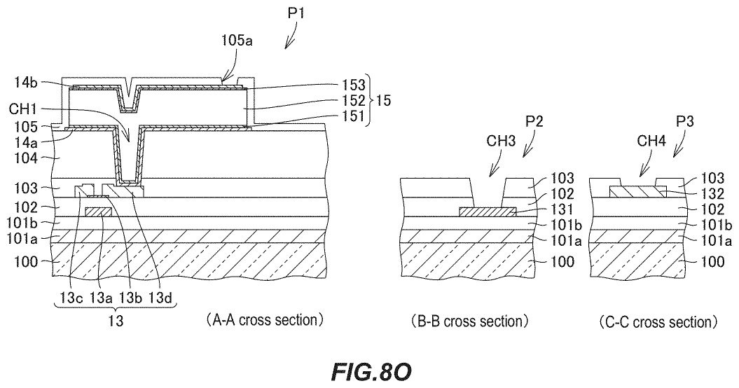

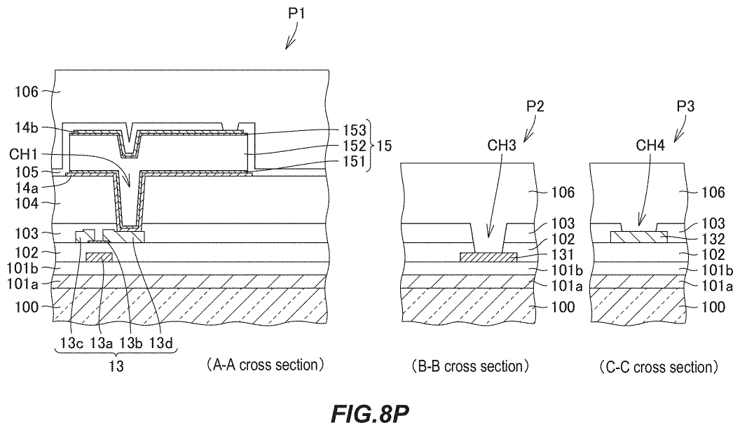

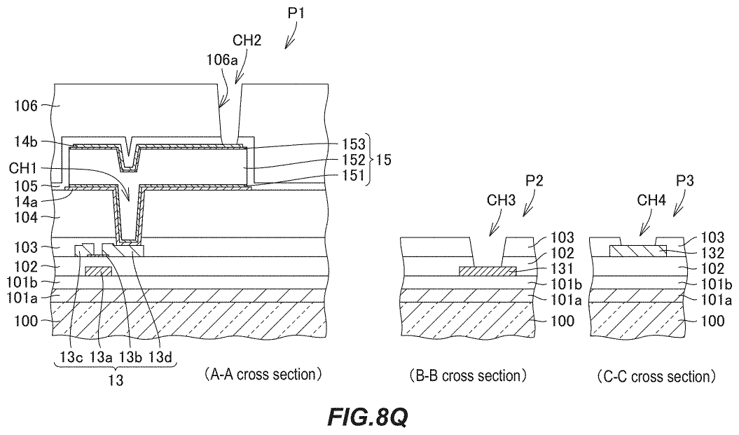

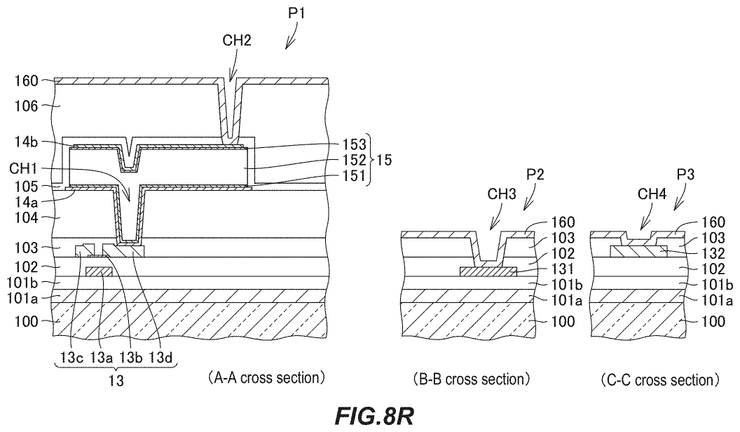

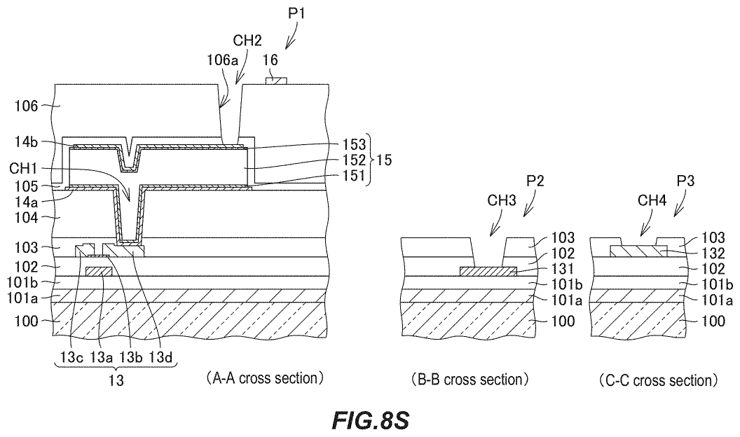

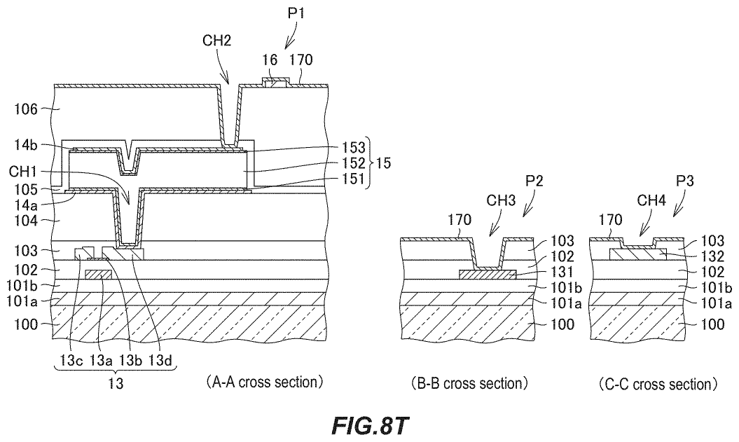

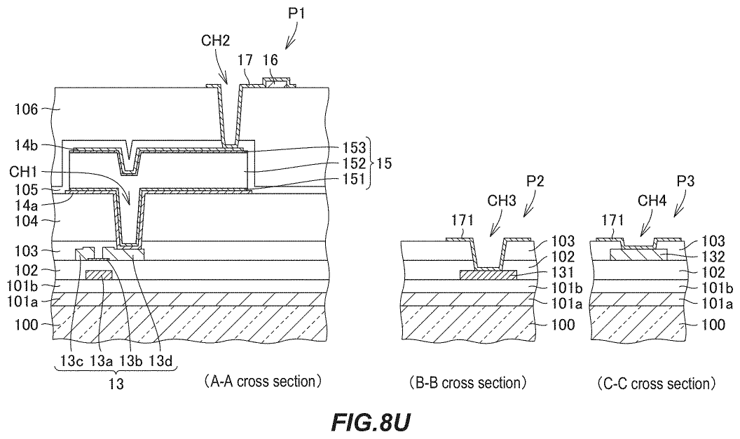

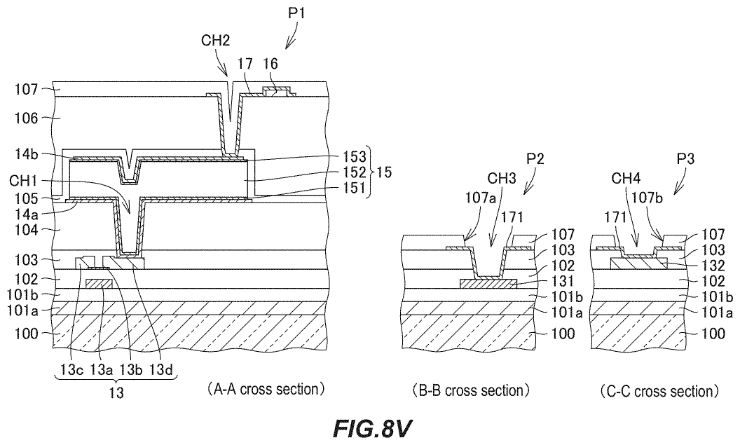

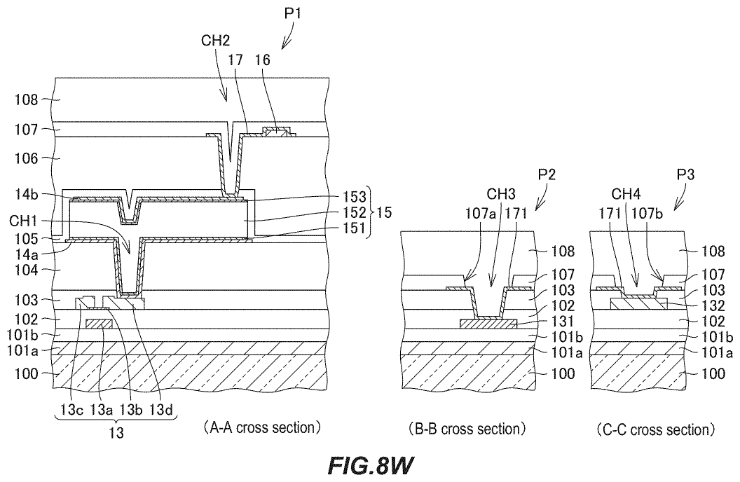

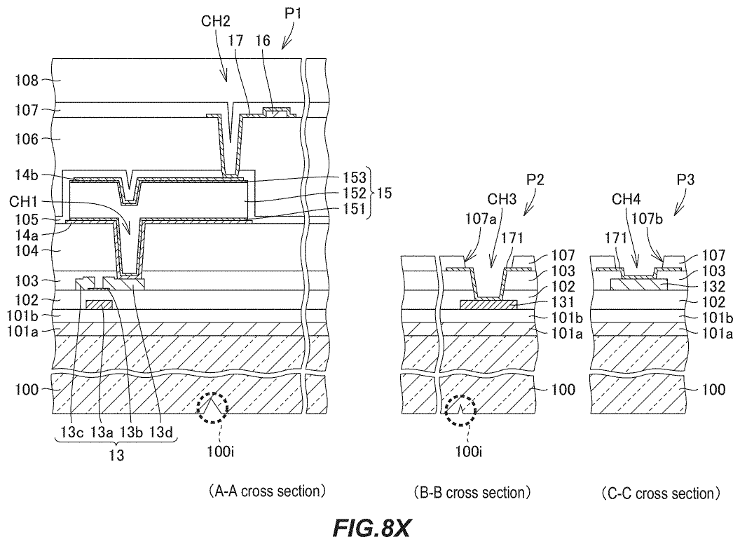

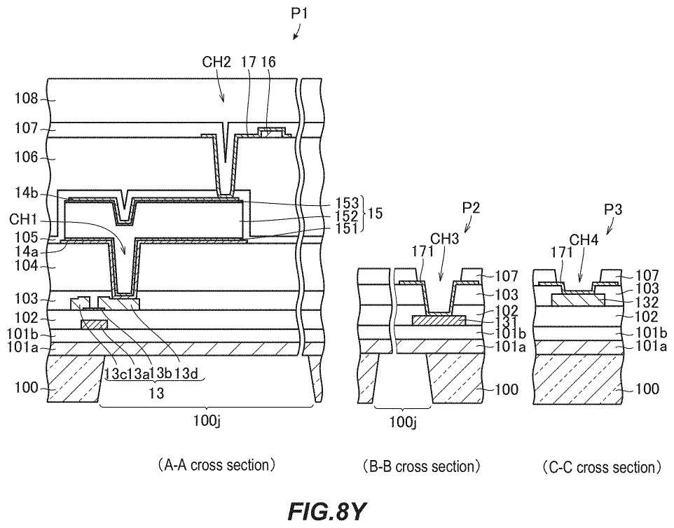

Next, the following description describes a method for producing the imaging panel 1. FIGS. 8A to 8Y are cross-sectional views illustrating respective steps of the process for producing the pixel area, the G terminal area P2, and the S terminal area P3 of the imaging panel 1, which illustrate the cross section (A-A cross section) of the pixel illustrated in FIG. 4, taken along line A-A, the cross section (B-B cross section) of the G terminal area illustrated in FIG. 5, taken along line B-B, and the cross section (C-C cross section) of the S terminal area illustrated in FIG. 6, taken along line C-C.

As illustrated in FIG. 8A, a conductive film made of, for example, molybdenum (Mo) is formed as the barrier layer 101a, by sputtering or vapor deposition, over an entirety of a surface on one side of the substrate 100. Thereafter, a thin film made of, for example, silicon nitride (SiN) is formed as the inorganic insulating film 101b by plasma CVD so as to cover the barrier layer 101a. Subsequently, a metal film made of titanium (Ti) and a metal film made of aluminum (Al) are laminated in this order by, for example, sputtering so as to form a metal film 130g covering the inorganic insulating film 101b.

Next, photolithography and wet etching are carried out so that the metal film 130g is patterned (see FIG. 8B). Through these steps, the gate electrode 13a is formed in the pixel area, as seen in the A-A cross section illustrated in FIG. 8B. Further, the gate layer 131 is formed on the inorganic insulating film 101b in the G terminal area, as seen in the B-B cross section illustrated in FIG. 8B. The metal film 130g in the S terminal area is removed, as seen in the C-C cross section illustrated in FIG. 8B.

Subsequently, silicon oxide (SiO₂) and silicon nitride (SiN) are laminated in this order over an entirety of the pixel area and the terminal areas by plasma CVD, to form the gate insulating film 102. Thereafter, a semiconductor layer formed with amorphous oxide semiconductor containing indium (In), gallium (Ga), and zinc (Zn) at a predetermined ratio is formed on the gate insulating film 102, and photolithography and dry etching are carried out so that the semiconductor layer is patterned (see FIG. 8C).

Through these steps, in the pixel area, the semiconductor active layer 13b is formed on the gate insulating film 102 at a position that overlaps with the gate electrode 13a, as seen in the A-A cross section illustrated in FIG. 8C. In the G terminal area, the gate insulating film 102 is formed so as to cover the gate layer 131, as seen in the B-B cross section illustrated in FIG. 8C, and the semiconductor layer is removed. Further, in the S terminal area, the gate insulating film 102 is formed on the inorganic insulating film 101b, as seen in the C-C cross section illustrated in FIG. 8C, and the semiconductor layer is removed.

Thereafter, titanium (Ti), aluminum (Al), and titanium (Ti) are laminated in this order by, for example, sputtering, to form a metal film 130s over the entirety of the pixel area and the terminal areas (see FIG. 8D).

Then, photolithography and wet etching are carried out so that the metal film 130s is patterned (see FIG. 8E). Through these steps, in the pixel area, the source electrode 13c and the drain electrode 13d are formed so as to be separated from each other on the semiconductor active layer 13b, as seen in the A-A cross section illustrated in FIG. 8E, whereby the TFT 13 is formed. Further, the metal film 130s is removed in the G terminal area, as seen in the B-B cross section illustrated in FIG. 8E, and the source layer 132 is formed on the gate insulating film 102 in the S terminal area, as seen in the C-C cross section illustrated in FIG. 8E.

Next, over the entirety of the pixel area and the terminal areas, the first insulating film 103 made of silicon nitride (SiN) is formed by, for example, plasma CVD (see FIG. 8F).

Subsequently, photolithography and wet etching are carried out so that the first insulating film 103 is patterned (see FIG. 8G). Through these steps, an opening 103a of the first insulating film 103 is formed on the drain electrode 13d in the pixel area, as seen in the A-A cross section illustrated in FIG. 8G. Further, in the G terminal area, a contact hole CH3 that passes through the gate insulating film 102 and the first insulating film 103 is formed on the gate layer 131, as seen in the B-B cross section illustrated in FIG. 8G. In the S terminal area, the contact hole CH4 is formed on the source layer 132, as seen in the C-C cross section illustrated in FIG. 8G.

Next, the second insulating film 104 made of acrylic resin or siloxane-based resin is applied over the entirety of the pixel area and the terminal areas by, for example, slit coating (see FIG. 8H).

Thereafter, the second insulating film 104 is patterned by photolithography (see FIG. 8I). Through these steps, an opening 104a of the second insulating film 104 is formed on the opening 103a in the pixel area, as seen in the A-A cross section illustrated in FIG. 8I, whereby the contact hole CH1 is formed. The second insulating film 104 in the terminal areas is removed, as seen in the B-B cross section and the C-C cross section illustrated in FIG. 8I.

Subsequently, over the entirety of the pixel area and the terminal areas, a metal film made of molybdenum niobium (MoN) is formed by, for example, sputtering, and photolithography and wet etching are carried out so as to pattern the metal film (see FIG. 8J). Through these steps, in the pixel area, the lower electrode 14a connected with the drain electrode 13d through the contact hole CH1 is formed on the second insulating film 104, as seen in the A-A cross section illustrated in FIG. 8J. The metal film formed in the terminal areas is removed, as seen in the B-B cross section and the C-C cross section illustrated in FIG. 8J.

Next, the n-type amorphous semiconductor layer 151, the intrinsic amorphous semiconductor layer 152, and the p-type amorphous semiconductor layer 153 are formed in the stated order by, for example, plasma CVD over the entirety of the pixel area and the terminal areas. Then, the transparent conductive film 141 made of ITO is formed on the p-type amorphous semiconductor layer 153 by, for example, sputtering (see FIG. 8K).

Thereafter, photolithography and dry etching are carried out so as to pattern the transparent conductive film 141 (see FIG. 8L). Through these steps, the upper electrode 14b is formed on the p-type amorphous semiconductor layer 153 in the pixel area, as seen in the A-A cross section illustrated in FIG. 8L. Besides, the transparent conductive film 141 in the terminal areas is removed, as seen in the B-B cross section and the C-C cross section illustrated in FIG. 8L.

Subsequently, photolithography and dry etching are carried out so that the p-type amorphous semiconductor layer 153, the intrinsic amorphous semiconductor layer 152, and the n-type amorphous semiconductor layer 153 are patterned (see FIG. 8M). Through these steps, the photoelectric conversion layer 15 is formed in the pixel area, as seen in the A-A cross section illustrated in FIG. 8M. Further, the p-type amorphous semiconductor layer 153, the intrinsic amorphous semiconductor layer 152, and the n-type amorphous semiconductor layer 153 in the terminal areas are removed, as seen in the B-B cross section and the C-C cross section illustrated in FIG. 8M.

Next, over the entirety of the pixel area and the terminal areas, the third insulating film 105 made of silicon nitride (SiN) is formed by, for example, plasma CVD (see FIG. 8N).

Thereafter, photolithography and wet etching are carried out so that the third insulating film 105 is patterned (see FIG. 8O). Through these steps, an opening 103a of the third insulating film 105 is formed on the upper electrode 14b in the pixel area, as seen in the A-A cross section illustrated in FIG. 8O. Further, the third insulating film 105 in the terminal areas is removed, as seen in the B-B cross section and the C-C cross section illustrated in FIG. 8O.

Subsequently, the fourth insulating film 106 made of acrylic resin or siloxane-based resin is formed over the entirety of the pixel area and the terminal areas by, for example, slit coating (see FIG. 8P). Thereafter, photolithography and wet etching are carried out so that the fourth insulating film 106 is patterned (see FIG. 8Q). Through these steps, an opening 106a of the fourth insulating film 106 is formed on the opening 105a of the third insulating film 105 in the pixel area, as seen in the A-A cross section illustrated in FIG. 8Q, whereby the contact hole CH2 is formed. The fourth insulating film 106 in the terminal areas is removed, as seen in the B-B cross section and the C-C cross section illustrated in FIG. 8Q.

Next, a metal film 160 is formed by laminating titanium (Ti), aluminum (Al), and titanium (Ti) in this order by, for example, sputtering over the entirety of the pixel area and the terminal areas (see FIG. 8R). Thereafter, photolithography and wet etching are carried out so that the metal film 160 is patterned (see FIG. 8S). Through these steps, in the pixel area, the bias line 16 is formed outside the contact hole CH2 on the fourth protection layer 106 in the pixel area, as seen in the A-A cross section illustrated in FIG. 8S. Further, the metal film 160 in the terminal areas is removed, as seen in the B-B cross section and the C-C cross section illustrated in FIG. 8S.

Subsequently, a transparent conductive film 170 made of ITO is formed over the entirety of the pixel area and the terminal areas by, for example, sputtering (see FIG. 8T). Thereafter, photolithography and dry etching are carried out so as to pattern the transparent conductive film 170 (see FIG. 8U). Through these steps, the transparent conductive film 17 that is connected with the bias line 16 on the fourth insulating film 106 and is connected with the upper electrode 14b through the contact hole CH2 is formed in the pixel area, as seen in the A-A cross section illustrated in FIG. 8U. Further, in the G terminal area, the transparent conductive layer 171 that is connected with the gate layer 131 through the contact hole CH3 is formed, as seen in the B-B cross section illustrated in FIG. 8U. In the S terminal area, the transparent conductive layer 171 that is connected with the source layer 132 through the contact hole CH4 is formed, as seen in the C-C cross section illustrated in FIG. 8U.

Next, over the entirety of the pixel area and the terminal areas, the fifth insulating film 107 made of silicon nitride (SiN) is formed by, for example, plasma CVD, and thereafter, the fifth insulating film 107 is patterned by photolithography (see FIG. 8V). Through these steps, the fifth insulating film 107 covering the transparent conductive film 17 is formed on the fourth insulating film 106 in the pixel area, as seen in the A-A cross section illustrated in FIG. 8V. In the G terminal area, the fifth insulating film 107 overlapping with a part of the transparent conductive layer 171 is formed outside the contact hole CH3, and an opening 107b of the fifth insulating film 107 is formed, as seen in the B-B cross section illustrated in FIG. 8V. In the S terminal area, the fifth insulating film 107 overlapping with a part of the transparent conductive layer 171 is formed outside the contact hole CH4, and an opening 107c of the fifth insulating film 107 is formed, as seen in the C-C cross section illustrated in FIG. 8V.

Subsequently, the sixth insulating film 108 made of acrylic resin or siloxane-based resin is applied over the entirety of the pixel area and the terminal areas by, for example, slit coating (see FIG. 8W). Thereafter, the sixth insulating film 108 is patterned by photolithography and dry etching (see FIG. 8X). Through these steps, the sixth insulating film 108 in the terminal areas is removed, as seen in the B-B cross section and the C-C cross section illustrated in FIG. 8X.

With the step illustrated in FIG. 8X, all of the elements in the pixel area and the terminal areas are formed on one of the surfaces of the substrate 100. In the present example, as illustrated in FIG. 8X, there is a scar 100i in a part where the pixel area and the terminal areas are provided, on a back surface of the substrate 100.

In this state, the substrate 100 is subjected to thin plate processing. Thin plate processing is an operation of etching the back surface of the substrate 100 with an etchant containing hydrofluoric acid. Through the thin plate processing, the dimple 100j is formed from the scar 100i part on the back surface of the substrate 100, as illustrated in FIG. 8Y. The barrier layer 101a provided on the substrate 100 contains a material having etching resistance against hydrofluoric acid. Therefore, it is unlikely that the barrier layer 101a would be etched in the thin plate processing, making it unlikely that the dimple 100j expands to an upper layer with respect to the barrier layer 101a. Therefore, the gate electrode 13a, the source electrode 13c, and the drain electrode 13d of the TFT 13, as well as the gate insulating film 102, and the like in the pixel area do not disappear due to the thin plate processing. Likewise, as the barrier 101a exists, the gate layer 131 and the source layer 132 in the terminal areas do not disappear due to the thin plate processing. As a result, the pixel area and the terminal areas are allowed to be appropriately conductive to one another, without line disconnection in the pixel area and the terminal areas.

Besides, in this example, the inorganic insulating film 101b is provided on the barrier layer 101a, which makes it unlikely that alkali ions, moisture, and the like contained in the substrate 100 would go from the dimple 100j formed on the substrate 100 through the barrier layer 101a. Therefore, the thin plate processing, even if carried out, would not adversely affect the properties of the TFTs 13 in the pixel area.

### (Operation of X-Ray Imaging Device 1000)

Here, operations of the X-ray imaging device 1000 illustrated in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 passes through an object S, and are incident on the scintillator 1A. The X-rays incident on the scintillator 1A are converted into fluorescence (scintillation light), and the scintillation light is incident on the imaging panel 1. When the scintillation light is incident on the photodiode 12 provided in each pixel in the imaging panel 1, the scintillation light is changed to charges by the photodiode 12 in accordance with the amount of the light. A signal according to the charges obtained by conversion by the photodiode 12 is read out by the signal reading unit 2B (see FIG. 2 and the like) through the source line 10 when the TFT 13 (see FIGS. 2, 3 and the like) is in the ON state according to a gate voltage (positive voltage) that is output from the gate control unit 2A through the gate line 11. Then, an X-ray image in accordance with the signal thus read out is generated in the control unit 2.

The embodiment of the present invention is thus described above, but the above-described embodiment is merely examples for implementing the present invention. The present invention, therefore, is not limited to the above-described embodiment, and the above-described embodiment can be appropriately varied and implemented without departing from the spirit and scope of the invention.

(1) The above-described embodiment is described with reference to an exemplary configuration in which a conductive film having resistance against hydrofluoric acid is used as the barrier layer 101a. The material for the barrier layer 101a, however, is not limited to this, and may be any material as long as it has resistance against hydrofluoric acid. For example, a semiconductor film may be used as the barrier layer 101a, or alternatively, an organic insulating film may be used.

As the semiconductor film used for the barrier layer 101a, a film of amorphous silicon, or a film of amorphous silicon doped with an impurity, may be used. Alternatively, a film of polysilicon, or a film of polysilicon doped with an impurity, may be used as the semiconductor film. Or alternatively, a film of microcrystal, or a film of microcrystal doped with an impurity, may be used as the semiconductor film. In a case where a semiconductor film is used as the barrier layer 101a, the barrier layer 101a preferably has a thickness of about 200 nm. In a case where the above-described semiconductor film is used as the barrier layer 101a, the barrier layer 101a is formed by plasma CVD in the step illustrated in FIG. 8A.

Further, polyimide may be used for forming the organic insulating film used as the barrier layer 101a. In a case where an organic insulating film is used as the barrier layer 101a, the barrier layer 101a preferably has a thickness of about 1 μm. In this case, in the step illustrated in FIG. 8A, polyimide is applied over one of the surfaces of the substrate 100 using a resin applying device, and thereafter, the substrate is subjected to an annealing treatment, so that the barrier layer 101a is formed.

(2) The above-described embodiment is described with reference to an exemplary configuration in which a layer including the barrier layer 101a and the inorganic insulating film 101b is used as the protection layer, but at least the barrier layer 101a may be provided in the protection layer. With the barrier layer 101a provided therein, it is possible to prevent the gate electrode 13a, the source electrode 13b, and the drain electrode 13d of the TFT 13, as well as the gate layer 131 and the source layer 132 in the terminal areas from disappearing when the substrate 100 is subjected to the thin plate processing. As a result, it is possible to prevent at least line disconnection.

1: An imaging panel that generates an image based on scintillation light that is obtained from X-rays transmitted through an object, the imaging panel comprising:
a substrate;
an active area formed on one of surfaces of the substrate;
a terminal area provided on an outer side with respect to the active area; and
a protection layer provided in the active area and the terminal area on the one of surfaces of the substrate,
wherein the active area has a plurality of elements including switching elements,
the terminal area has a terminal element connected with any of the plurality of elements,
the protection layer includes a barrier layer in contact with the one of surfaces of the substrate, and is provided in a lower layer with respect to the plurality of elements and the terminal element, and
the barrier layer contains a material having resistance against an etching material that can etch the substrate.

2: The imaging panel according to claim 1,
wherein the protection layer further includes an inorganic insulating film in contact with the barrier layer, and
the inorganic insulating film is provided in a lower layer with respect to the plurality of elements and the terminal element.

3: The imaging panel according to claim 1,
wherein the barrier layer is formed with a conductive film.

4: The imaging panel according to claim 1,
wherein the barrier layer is formed with a semiconductor film.

5: The imaging panel according to claim 1,
wherein the barrier layer is formed with an organic insulating film.

6: A method for producing an imaging panel that generates an image based on scintillation light that is obtained from X-rays transmitted through an object, the imaging panel producing method comprising:
forming a barrier layer in an active area and a terminal area on one of surfaces of a substrate;
forming a plurality of elements including switching elements, in an upper layer with respect to the barrier layer in the active area;
forming a terminal element in an upper layer with respect to the barrier layer in the terminal area; and
etching the substrate,
wherein the barrier layer contains a material having resistance against an etching material used in the step of etching the substrate.

7: The imaging panel producing method according to claim 6,
further comprising forming an inorganic insulating film on the barrier layer, wherein the plurality of elements are formed in an upper layer with respect to the inorganic insulating film.

8: The imaging panel producing method according to claim 6,
wherein the etching material contains hydrofluoric acid.
